(19) United States
(12) Patent Application Publication
(10) Pub. No.: US 2016/0336440 A1
(43) Pub. Date: Nov. 17, 2016

(54) SUPER JUNCTION DEVICE AND METHOD OF MANUFACTURING THE SAME

(71) Applicant: SUPER GROUP SEMICONDUCTOR CO., LTD., New Taipei City (TW)

(72) Inventors: Hsiu-Wen HSU, Hsinchu County (TW); Chun-Ying YEH, Hsinchu City (TW); Yuan-Ming LEE, Taichung City (TW)

(21) Appl. No.: 15/092,607

(22) Filed: Apr. 6, 2016

(30) Foreign Application Priority Data
May 14, 2015 (TW) 104115419

(51) Int. Cl. H01L 29/78; H01L 29/10; H01L 29/66; H01L 29/06

(52) U.S. Cl. CPC H01L 29/7813; H01L 29/0634; H01L 29/1095; H01L 29/66734; H01L 29/66545; H01L 29/1083

(57) ABSTRACT

A method of manufacturing super junction device includes forming a first epitaxial layer on a semiconductor substrate. The first epitaxial layer is patterned to form a trench. The trench has a first sidewall region, a second sidewall region and a bottom region. The bottom region is positioned in between the first and second sidewall regions. A second epitaxial layer is formed on the first sidewall region, the second sidewall region and the bottom region. A portion of the second epitaxial layer on the first sidewall region and the second sidewall region is removed. An oxide layer in contact with the second epitaxial layer is formed. A gate layer in contact with the oxide layer is formed.

### RELATED APPLICATIONS

This application claims priority to Taiwanese Application Serial Number 104115419, filed May 14, 2015, which is herein incorporated by reference.

### BACKGROUND

1. Field of Invention

The present invention relates to a super junction device and method of manufacturing the same. More particularly, the present invention relates to a MOSFET super junction device.

2. Description of Related Art

Semiconductor devices are widely used in electronic products. However, the formation of the epitaxial layer in a semiconductor device is complex and hard to control. Therefore, there is an urgent issue of how to control the high aspect ratio of the trench and provide a robust super junction device.

### SUMMARY

The instant disclosure provides a method of manufacturing super junction device. The method includes forming a first epitaxial layer on a semiconductor substrate. Then, the first epitaxial layer is patterned to form a trench. The trench has a first sidewall region, a second sidewall region and a bottom region. The bottom region is positioned in between the first and second sidewall regions. Subsequently, a second epitaxial layer on the first sidewall region, the second sidewall region and the bottom region are formed. Next, a portion of the second epitaxial layer on the first sidewall region and the second sidewall region is removed. Following that, an oxide layer in contact with the second epitaxial layer is formed. Finally, a gate layer in contact with the oxide layer is formed.

The instant disclosure also provides a super junction device including a semiconductor substrate, a first epitaxial layer, a trench, a second epitaxial layer, an oxide layer and a gate layer. The first epitaxial layer is disposed on the semiconductor substrate. The trench, which is formed by patterning the first epitaxial layer, has a first sidewall region, a second sidewall region and a bottom region respectively corresponding to a first sidewall, a second sidewall of the first epitaxial layer and a surface of the semiconductor substrate. The second epitaxial layer is disposed on the first sidewall region, the second sidewall region and the bottom region of the trench. The oxide layer is disposed on the second epitaxial layer. The gate layer is disposed in the trench and covered by the oxide layer.

The super junction device of the instant disclosure can be produced by simple manufacturing process, which controls the formation of the epitaxial layer and the contour of the trench. The conductive resistance can be reduced, the breakdown voltage is increased, and the power device will have higher stability and lower production cost.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIGS. 1A-1I are cross-sectional views of a process manufacturing a trench of a super junction device in accordance with an embodiment of the instant disclosure;

FIGS. 2A-2C are cross-sectional views of a process manufacturing an oxide layer of a super junction device in accordance with an embodiment of the instant disclosure;

FIGS. 3A-3E are cross-sectional views of a process manufacturing a gate layer and a metal layer of a super junction device in accordance with an embodiment of the instant disclosure;

FIG. 4 is a cross-sectional view of a super junction in accordance with an embodiment of the instant disclosure;

FIG. 5 is a cross-sectional view of a super junction in accordance with an embodiment of the instant disclosure; and

FIG. 6 is a cross-sectional view of a super junction in accordance with an embodiment of the instant disclosure.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

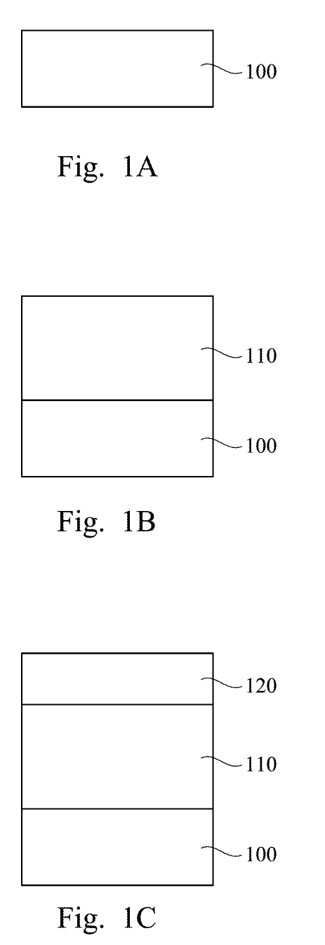

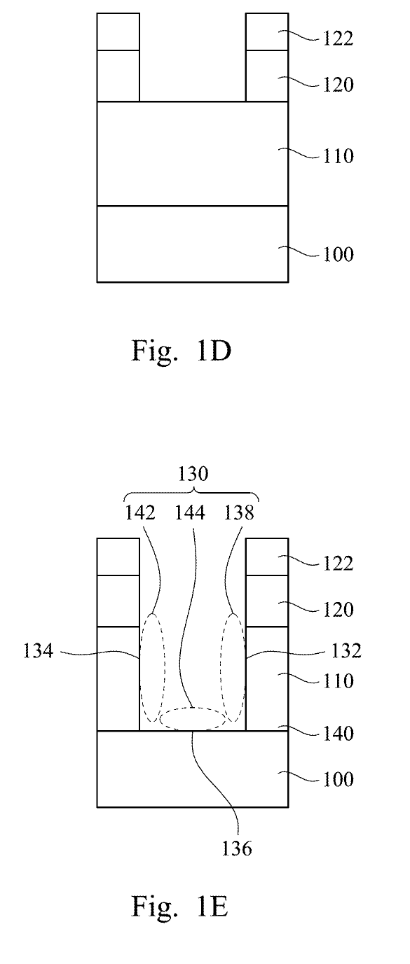

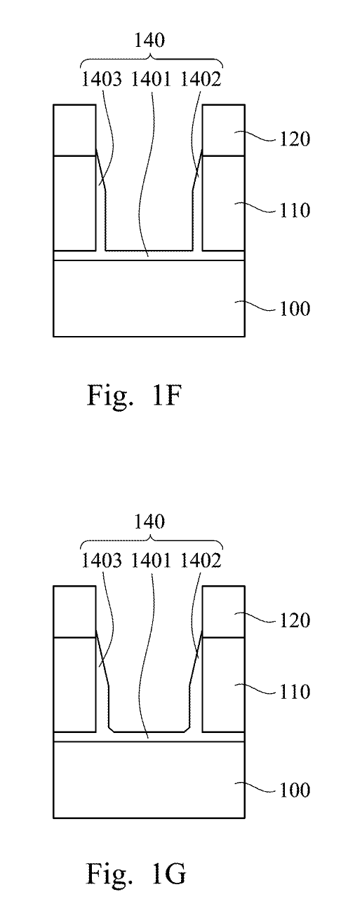

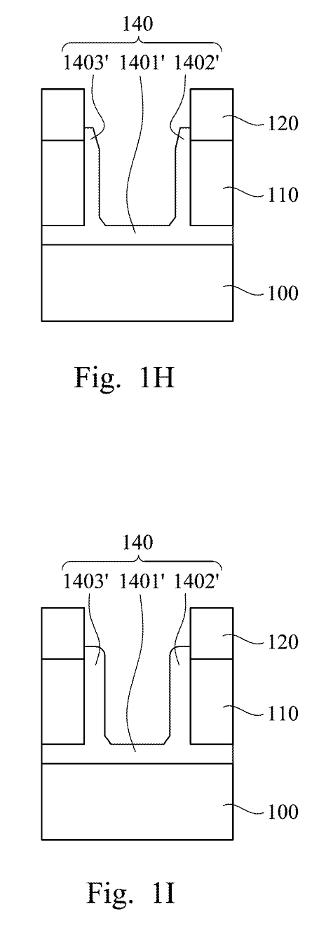

FIGS. 1A-1I are cross-sectional views of a process manufacturing a trench of a super junction device in accordance with an embodiment of the instant disclosure.

Please refer to FIG. 1A. The super junction device is constructed on a semiconductor substrate 100. The material of the semiconductor substrate 100 may be, for example, monocrystalline silicon or the like. The semiconductor substrate 100 has a conductive dopant, which may be n-type or p-type dopant. The n-type dopant may be, for example, arsenic, and the p-type dopant may be boron. The dopant concentration may vary according to practical needs, device structure or other properties.

Pleas refer to FIG. 1B. A first epitaxial layer 110 is formed on the semiconductor substrate 100. The first epitaxial layer 110 may be formed by chemical vapour deposition (CVD), plasma enhanced chemical vapour deposition (PECVD), atom layer deposition (ALD) or any other suitable deposition. The first epitaxial layer 110 has a first conductive type. In some embodiments of the instant disclosure, the first epitaxial layer employs a light p-type dopant.

Next, the first epitaxial layer 110 is patterned to form a trench 130. The process includes the steps shown in FIG. 1C, FIG. 1D and FIG. 1E. Firstly, a hard mask is formed on the first epitaxial layer 110 as shown in FIG. 1C. The hard mask may be an oxide layer 120 formed on the first epitaxial layer 110 by spreading, spin coating, sputtering, heating growth or the like. Following that, as shown in FIG. 1D, a light mask 122 is formed on the oxide layer 120. The light mask 122 may be formed with an opening in advance. Alternatively, the light mask may be formed with an opening at this stage by photolithography and etching to form the opening on the light mask 122. The oxide layer 120 under the opening of the light mask 122 is removed so as to achieve the patterning of the hard mask.

Please refer to FIG. 1E. Patterning the first epitaxial layer 110 involves etching the first epitaxial layer 110 that is underneath the opening, which is defined by the light mask 122 and the oxide layer 120. The depth of etching should be at least expose the semiconductor substrate 100. The first epitaxial layer 110 after etching has a depressed trench 130. A first sidewall 132 and the a second sidewall 134 of the first epitaxial layer 110 corresponds to the first sidewall region 138 and a second sidewall region 142 of the trench 130 respectively. A surface portion 136 of the semiconductor substrate 100 is exposed because of the etching of the first epitaxial layer 110, and the surface portion 136 corresponds to a bottom 144 of the trench 130. After the formation of the trench 130, the light mask 122 is removed. In one embodiment of the instant disclosure, the first sidewall region 138 and the second sidewall region 142 of the trench 130 are orthogonal to the bottom region 144.

Please refer to FIGS. 1E and 1F. A second epitaxial layer 140 is formed on the first sidewall region 138, second sidewall region 142 and the bottom region 144 of the trench 130. The second epitaxial layer 140 includes 1401, 1402, 1403 deposited to the places corresponding to the bottom region 144, the first sidewall region 138 and the second sidewall region 142 respectively. The deposition may be achieved by CVD, ATD or any other suitable deposition to form the second epitaxial layer 140 over the first sidewall region 138, the second sidewall region 142 and the bottom region 144 of the trench 130. The second epitaxial layer 140 has a second conductive type, and the second conductive type is different from the first conductive type. In one embodiment of the instant disclosure, the first conductive type is p and the second conductive type is n.

In addition, when the second epitaxial layer 140 is formed, as shown in FIG. 1F, a portion of the second epitaxial layer 1401 at the bottom region 144 diffuses toward the first epitaxial layer 110. The semiconductor 100 diffuses toward the interface between the first epitaxial layer 110. The first epitaxial layer 110 and the second epitaxial layer 140 may have different dopant concentrations. In the instant embodiment, the second epitaxial layer 140 has a higher dopant concentration so as to diffuse by gradient.

Please refer to FIG. 1G. A portion of the second epitaxial layer 140 is removed. More specifically, because of different deposition speed at different regions, the speed of deposition of the second epitaxial layer 1401 at the bottom region 144 is slower compared to the second epitaxial layer 1402 and 1403 on the first sidewall region 138 and the second sidewall region 142. Therefore in a given time frame, the second epitaxial layer 1401 cannot increase its volume very quick, but the first sidewall 132 and the second sidewall 134 increases its thickness in a rapid speed. Consequently, the trench 130 has different height, depth and width proportion, and the ratio is uneven. Therefore, in the manufacturing process, the second epitaxial layers 1402, 1403 on the first sidewall region 138 and the second sidewall region 142 has to be removed by etching so as to avoid the second epitaxial layers 1402, 1403 at the opening of the trench 130 being too thick to allow any access. The second epitaxial layer 140 has to go through repeated deposition and etching of the second epitaxial layers 1402, 1403 on the first sidewall region 138 and second sidewall region 142 and gradually form into a predetermined super junction structure.

Please refer to FIG. 1H. In the multiple back etching of the second epitaxial layer 140 formation, it can ensure the super junction undergoes fine tuning. In some embodiments of the instant disclosure, the deposition of the second epitaxial layer 140 and the selective etching of the second epitaxial layers 1402, 1403 may repeat twice or even more. As a result, the thickness of the second epitaxial layer 140 can be controlled in its growth. As shown in FIG. 1H, the thickness of the second epitaxial layer 1401′ at the bottom 136 increases, and the width of the second epitaxial layers 1402′, 1403′ at the first sidewall 132 and second sidewall 134 is limited in the multiple etching back process, and therefore the access of the trench 130 is not affected.

After at least twice deposition and selective etching cycle of the second epitaxial layer 140, the contour of the super junction is defined by the second epitaxial layer 140, as shown in FIG. 1I. The super junction structure of the instant disclosure is achieved by the deposition and etching of the existing epitaxial layer, and the structure detail can be fine tuned in the deposition/back etching cycle so as to form the orthogonal super junction structure with readily accessible trench. In addition, because of repeated deposition/etching back in the formation of the epitaxial layer instead of filling back, the size and contour of the second epitaxial layer 140 can be controlled in the formation thereof. As a result, a width of the second epitaxial layer 140 is smaller than a width of the first epitaxial layer 110, such that the high aspect ratio of the trench 130 can be maintained, and the access to the trench is clear because the second epitaxial layers 1401′, 1403′ will not merge.

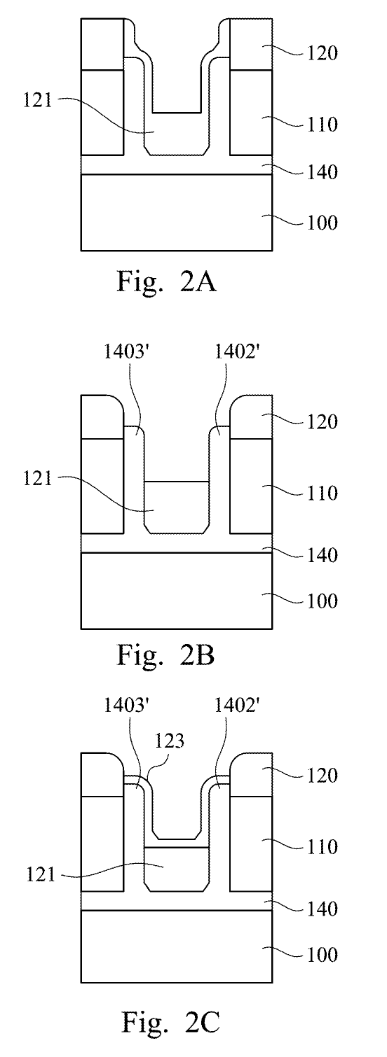

FIGS. 2A-2C are cross-sectional views of a process manufacturing an oxide layer of a super junction device in accordance with an embodiment of the instant disclosure.

Please refer to FIG. 2A. A first oxide layer 121 is formed, and it is in contact with the second epitaxial layer 140. The second epitaxial layer 140 undergoes repeated deposition and etching back, the first oxide layer 121 coats on the second epitaxial layer 140 to completely cover the second epitaxial layer 140. The first oxide layer 121 may be formed by spin coating, sputtering, evaporation deposition, heating growth or any other suitable means. The thickness of the first oxide layer 121 may vary according to the device requirement. In some embodiments, the thickness of the first oxide layer 121 in the trench 130 is thicker than that of the second epitaxial layer 140 in the trench 130.

Please refer to FIG. 2B. A portion of the first oxide layer 121 is removed. The first oxide layer 121 on the second epitaxial layers 1402′, 1403′ is removed by etching back so as to expose the second epitaxial layers 1402′, 1403′. However, the first oxide layer 121 at the bottom region 144 of the trench is not removed. Subsequently, a gate oxide layer 123 is coated on the second epitaxial layers 1402′, 1403′ and the first oxide layer 121, as shown in FIG. 2C.

Before the formation of the gate oxide layer 123, at least one sacrifice oxide layer (not shown) may be deposited. Then, the sacrifice oxide layer is removed by etching back. In the coating (deposition) and removing (etching back) process, the surface of the second epitaxial layers 1402′, 1403′ can be smoothed. Consequently, when applying other materials over the second epitaxial layer 140, the compatibility and stability are improved.

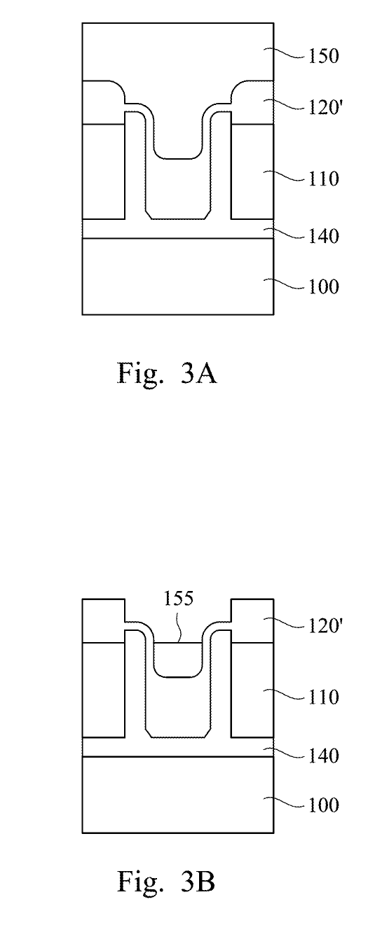

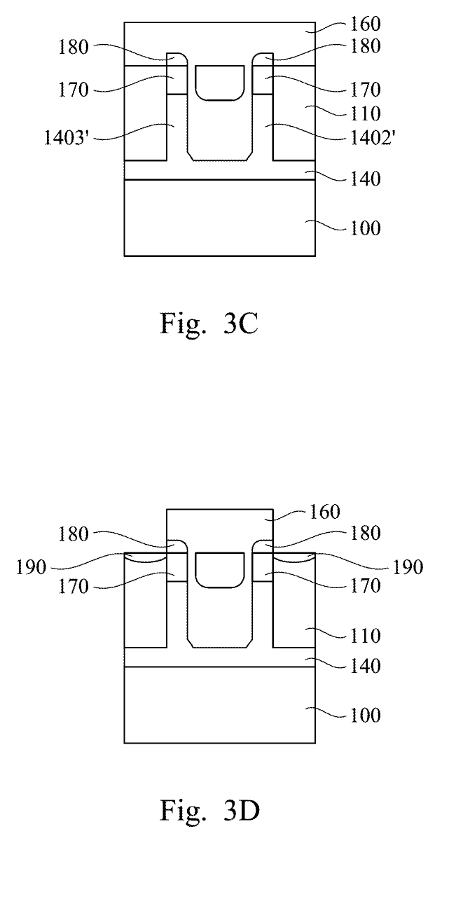

Please refer to FIG. 3A. The oxide layer 120′ includes the first oxide layer 121 and the gate oxide layer 123 in FIG. 2C. After the formation of the second epitaxial layer 140 of the super junction, a gate polysilicon 150 is deposited to fill in the trench 130 and overfill to the oxide layer 120′, such that the gate polysilicon 150 completely covers the oxide layer 120′. The deposition of the gate polysilicon 150 may be chemical vapour deposition, atom layer deposition or any other suitable process. The gate polysilicon 150 is only in contact with the oxide layer 120′. Next, a gate layer 155 is formed in the trench 130 by etching back, as shown in FIG. 3B.

Please refer to FIG. 3C. a first type body 170 is formed on the second epitaxial layer 1402′, and the first type body 170 is formed on the second epitaxial layer 1403′. Then, a source 180 is formed on the two first type body 170. Following that, a isolation oxide layer 160 is formed on the oxide layer 120′ and the gate layer 155. The material of the isolation oxide layer 160 may be the same as the oxide layer 120, and therefore the isolation oxide layer 160 that includes the oxide layer 120 are denoted as 160 in FIG. 3C. The isolation oxide layer 160 fills in the depression of the gate layer 155 to level with the oxide layer 120′. Subsequently, the isolation oxide layer 150 is planarized by CMP. Please refer to FIG. 3D. a portion of the isolation oxide layer 160 is removed by etching, and the first epitaxial layer 110 can be exposed. Next, contact implant can be carried out on the first epitaxial layer 110 to form a contact layer 190. Please refer to FIG. 3E. A metal layer 200 is formed on the contact layer 190 and the isolation layer 160.

The abovementioned epitaxial layer deposition/etching cycle can precisely control the contour of the second epitaxial layer 140 of the super junction device 10, especially the width. After repeated fine tuning, the width of the second epitaxial layer 140 is smaller than that of the first epitaxial layer 110. The height, depth and width ratio of the trench 130 can be well maintained, and the surface filed is reduced. Overall, the super junction device can endure higher voltage current. The resistance and thickness of the second epitaxial layer 140 are adjusted to a greater extent in the repeated cycle. The damage caused by irregular breakdown is therefore reduced. Compared to conventional process, the instant disclosure provides a simplified manufacturing process and effectively controls the structure of the super junction.

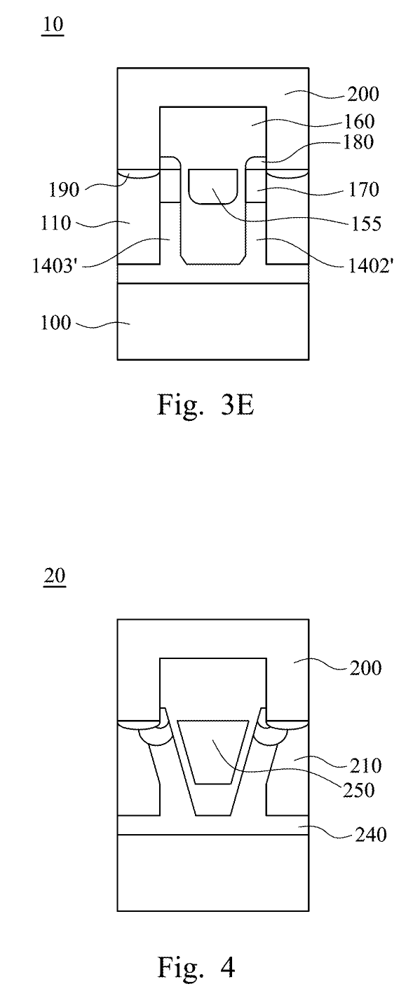

Please refer to FIG. 4. According to other embodiments of the instant disclosure, a super junction device 20 has a similar structure as the super junction device 10 shown in FIG. 3E. The difference between the super junction devices 20 and 10 arises from the second epitaxial layer 240. The second epitaxial layer 240 of the super junction device 20 at the first sidewall 132 and the second sidewall 134 is not orthogonal to the bottom 136. The second epitaxial layer 240 expands outwardly toward the first epitaxial layer 210. After repeated deposition/etching process, the second epitaxial layer 240 is shaped to a funnel which reduces from the trench opening toward the semiconductor substrate 100. Therefore, when the first oxide layer 121 and the gate layer 155 are formed, the contour of the gate layer 155 changes accordingly to an inversed trapezoid. The super junction device produced by the abovementioned process may have different angles between the second epitaxial layer and the bottom. Alternatively, the second epitaxial layer may expand outwardly (toward the first epitaxial layer). The second epitaxial layer 240 has a faster deposition rate at the bottom, and the number of deposition/etching back cycle of the second epitaxial layer 140 may be reduced.

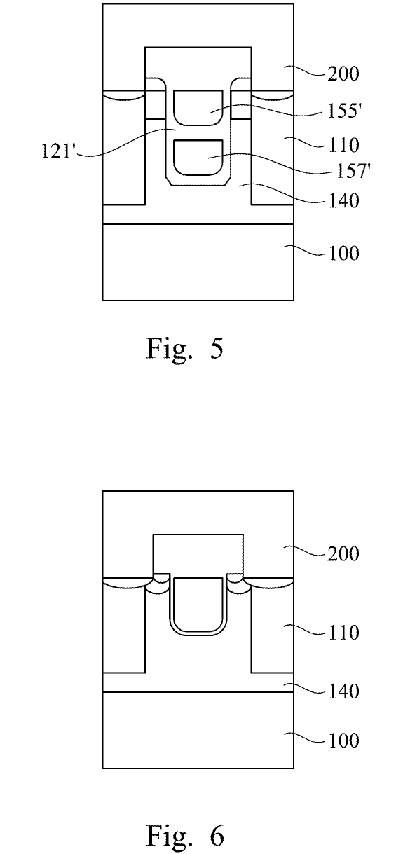

According to other embodiments of the instant disclosure, the difference between the super junction device shown in FIG. 5 and the super junction device 10 shown in FIG. 3E arises from the gate layer. In the instant embodiment, the gate layer includes two gate electrodes 155′, 157′. The formation of the gate electrodes starts from FIG. 11. The gate electrode (or grounder floating) 157′ is formed, then an oxide layer 121′ is formed, and finally the gate electrode 155′ is formed. The oxide layer 121′ is disposed between the two gate electrodes 155′, 157′ for separation and covers the two gate electrodes 155′, 157′.

According to some embodiments of the instant disclosure, the difference between the super junction device shown in FIG. 6 and the super junction device 10 shown in FIG. 3E arises from the thickness of the second epitaxial layer. In the instant embodiment, the thickness of the second epitaxial layer 140 at the bottom region is even thicker than the thickness of the second epitaxial layer 1401′. The high aspect ratio of the trench 130 can be finely controlled without removal of a portion of the second epitaxial layer on the first sidewall region and the second sidewall region. In addition, the thickness of the oxide layer decreases with respect to the super junction device 10.

The voltage endurance and resistance are two main indicators of a device performance. The instant disclosure provides a method that adjusts the contour of the epitaxial layer in its natural growth period, such that a narrower profile, higher high aspect ratio, trench accessibility are all ensured. The epitaxial layer is narrower and has even thickness, and therefore the electrical potential reaches charge balance with reduce surface filed. A smoother electrical field distribution at the sidewalls of the trench can be obtained. Consequently, the breakdown voltage is elevated and the conduction resistance is reduced. The damage to the components caused by breakdown can be limited. The super junction structure can be employed in existing planar MOSFET, trench MOSFET, LDMOS, BCD, UHV and other associated process.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A method of manufacturing super junction device, comprising:
forming a first epitaxial layer on a semiconductor substrate;
patterning the first epitaxial layer to form a trench, the trench having a first sidewall region, a second sidewall region and a bottom region, the bottom region positioned in between the first and second sidewall regions;
forming a second epitaxial layer on the first sidewall region, the second sidewall region and the bottom region;
removing a portion of the second epitaxial layer on the first sidewall region and the second sidewall region;
forming an oxide layer in contact with the second epitaxial layer; and
forming a gate layer in contact with the oxide layer.

2. The method of manufacturing super junction device of claim 1, wherein removing a portion of the second epitaxial layer on the first sidewall region and the second sidewall region comprises repeating a plurality of times of removing a portion of the second epitaxial layer on the first sidewall region and the second sidewall region.

3. The method of manufacturing super junction device of claim 1, wherein before patterning the first epitaxial layer further comprises:
forming a hard mask on the first epitaxial layer;
forming a light mask on the hard mask; and
patterning the hard mask through the light mask.

4. The method of manufacturing super junction device of claim 1, wherein forming the second epitaxial layer further comprises:
forming a first oxide layer on the second epitaxial layer;
removing first oxide layer on the second epitaxial layer over the first sidewall region and the second sidewall region; and
forming a gate oxide layer on the second epitaxial layer.

5. The method of manufacturing super junction device of claim 1, wherein forming the gate layer on the oxide layer comprises:
depositing a gate polysilicon to fill the trench and over the oxide layer; and
etching the gate polysilicon to form the gate layer in the trench.

6. The method of manufacturing super junction device of claim 5, wherein after forming the gate layer in contact with the oxide layer further comprises:
forming a first type body on the second epitaxial layer on the first sidewall region and the second sidewall region respectively;
forming a source on each of the first type body;
forming an isolation oxide layer on the oxide layer and the gate layer;
removing the isolation oxide layer on the first epitaxial layer;
forming a contact layer in the first epitaxial layer; and
forming a metal layer on the isolation oxide layer and the contact layer.

7. The method of manufacturing super junction device of claim 1, wherein the second epitaxial layer at the bottom region diffuses in between the first epitaxial layer and the semiconductor substrate.

8. The method of manufacturing super junction device of claim 1, wherein the second epitaxial layer on the first sidewall region and the second sidewall region has a thickness, and the thickness is less than a thickness of the first epitaxial layer.

9. The method of manufacturing super junction device of claim 1, wherein the second epitaxial layer on the first sidewall region and the second sidewall region is non-orthogonal to the bottom region of the trench.

10. A super junction device, comprising:
a semiconductor substrate;
a first epitaxial layer disposed on the semiconductor substrate;
a trench formed by patterning the first epitaxial layer, the trench comprising a first sidewall region, a second sidewall region and a bottom region respectively corresponding to a first sidewall, a second sidewall of the first epitaxial layer and a surface of the semiconductor substrate;
a second epitaxial layer disposed on the first sidewall region, the second sidewall region and the bottom region of the trench;
an oxide layer disposed on the second epitaxial layer; and
a gate layer disposed in the trench and covered by the oxide layer.

11. The super junction device of claim 10, wherein the first epitaxial layer has a first conductive type, and the second epitaxial layer has a second conductive type.

12. The super junction device of claim 10, wherein the second epitaxial layer on the first sidewall region and the second sidewall region has a thickness respectively, and the thickness is smaller than a thickness of the first epitaxial layer.

13. The super junction device of claim 10, wherein the second epitaxial layer at the bottom region comprises the second epitaxial layer diffuses to in between the first epitaxial layer and the semiconductor substrate.

14. The super junction device of claim 10, wherein the second epitaxial layer on the first sidewall region and the second sidewall region is non-orthogonal to the bottom region of the trench.

15. The super junction device of claim 10, wherein the gate layer comprises two gate electrodes, and the two gate electrodes are covered and isolated by the oxide layer.
